(19) United States
(12) Patent Application Publication
(10) Pub. No.: US 2010/0091475 A1
(43) Pub. Date: Apr. 15, 2010

(54) Electrostatic Discharge (ESD) Shielding For Stacked ICs

(75) Inventors: Thomas R. Toms, Dripping Springs, TX (US); Reza Jalilizeinali, Oceanside, CA (US); Shiqun Gu, San Diego, CA (US)

Correspondence Address: QUALCOMM INCORPORATED, 5775 MOREHOUSE DR., SAN DIEGO, CA, 92121, US

(73) Assignee: QUALCOMM INCORPORATED, San Diego, CA (US)

(21) Appl. No.: 12/251,802

(22) Filed: Oct. 15, 2008

(51) Int. Cl. H05K 9/00; H01L 21/00

(52) U.S. Cl. 361/816; 438/107; 257/E21.001

(57) ABSTRACT

An unassembled stacked IC device includes an unassembled tier. The unassembled stacked IC device also includes a first unpatterned layer on the unassembled tier. The first unpatterned layer protects the unassembled tier from ESD events.

### TECHNICAL FIELD

The present disclosure generally relates to stacked integrated circuits (ICs). More specifically, the present disclosure relates to shielding stacked ICs from electrostatic discharge.

### BACKGROUND

Electrostatic discharge (ESD) events are a common part of everyday life and some of the larger discharges are detectable by the human senses. Smaller discharges go unnoticed by human senses because the ratio of discharge strength to surface area over which the discharge occurs is very small.

ICs have been shrinking at an incredible rate over past decades. By way of example, transistors in ICs have shrunk to 45 nm and will likely continue to shrink. As transistors shrink in size, the supporting components around transistors generally shrink as well. The shrinking of ICs decreases surface area. Thus, the ratio for a given discharge strength to surface area increases with smaller component sizes, and the components become susceptible to a larger range of ESD events.

An ESD event occurs when an object at a first charge comes near or into contact with an object at second, lower charge. The differential discharges as a single event. Rapid transfer of charge from the first object to second object occurs such that the two objects are at approximately equal charge. Where the object with lower charge is an IC, the discharge attempts to find the path of least resistance through the IC. Typically, this path flows through interconnects. Any part of this path that is unable to withstand the energy associated with the discharge sustains damage. Such damage often occurs in the gate oxide, which is generally the link most susceptible to discharge in ICs. When the gate oxide is damaged, it typically changes from an insulator to a conductor, such that the IC will no longer function as desired. Alternative mechanisms of damage for the ESD event include rupturing of the gate oxide in a through silicon via to create a short circuit in the device or fusing of the metal in an interconnect to create an open circuit in the device.

Fabrication sites where the manufacturing of integrated circuits is carried out have matured and implemented procedures to prevent ESD through integrated circuits during manufacturing. For example, design rules are used to assure that large charges do not accumulate during manufacturing. Conventionally, ESD protective structures are also built into the substrate and connected to the devices for protection. These structures consume a considerable amount of area (tens to hundreds of square microns for each ESD buffer) on the substrate that could otherwise be used for active circuitry. However, an ESD event may still occur during the process of manufacturing an IC. Detecting such damage sites in an IC is difficult, and the first sign that such damage occurred during manufacture typically occurs when the end product does not function as desired. As a result, a significant amount of time and resources may be spent manufacturing a device that does not function correctly.

One recent development in further advancing ICs capabilities is stacking integrated circuits to form a 3-D structure or stacked IC. This allows multiple components to be built into a single chip in separate tiers. For example, a memory cache may be built on top of a microprocessor. The resultant stacked IC has significantly higher densities of devices and significantly more complex manufacturing methods. It is anticipated that tier-to-tier connection densities in stacked ICs will exceed 100,000/cm².

For stacked ICs, manufacturers may perform a first set of IC manufacturing processes at one fabrication site and ship that IC tier to a second fabrication site that performs a second set of manufacturing processes for the second tier. A third site may then assemble the tiers into the stacked IC. When tiers of the integrated circuits leave the controlled environment of the manufacturing sites, they are exposed to potential ESD events that can render an entire stacked IC useless. Before the individual tiers are stacked, (i.e., bonded together to create the stacked IC), the tiers are especially vulnerable to ESD events.

As a result, there is a need to protect individual tiers of stacked integrated circuits from ESD events when transported outside of controlled environments during the manufacturing process.

### BRIEF SUMMARY

According to one aspect of the disclosure, an unassembled stacked IC device includes an unassembled tier. The unassembled stacked IC device also includes a first unpatterned layer on the unassembled tier. The first unpatterned layer protects the unassembled tier from ESD events.

According to another aspect of the disclosure, a method for manufacturing a stacked IC device includes manufacturing a tier of the stacked IC device. The method also includes depositing an unpatterned layer on the tier before transporting to an assembly plant. The unpatterned layer protects the tier from ESD events.

According to yet another aspect of the disclosure, a method for manufacturing a stacked IC device includes altering an unpatterned layer protecting a tier of a stacked IC device from ESD events to allow the tier of the stacked IC device to be integrated into the stacked IC device. The method also includes integrating the tier into the stacked IC device.

According to a further aspect of the disclosure, an unassembled stacked IC device includes means for shielding the unassembled stacked IC device from ESD events prior to assembling the stacked IC device.

The foregoing has outlined rather broadly the features and technical advantages of the present disclosure in order that the detailed description that follows may be better understood. Additional features and advantages will be described hereinafter which form the subject of the claims of the disclosure. It should be appreciated by those skilled in the art that the conception and specific embodiments disclosed may be readily utilized as a basis for modifying or designing other structures for carrying out the same purposes of the present disclosure. It should also be realized by those skilled in the art that such equivalent constructions do not depart from the technology of the disclosure as set forth in the appended claims. The novel features which are believed to be characteristic of the disclosure, both as to its organization and method of operation, together with further objects and advantages will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

For a more complete understanding of the present disclosure, reference is now made to the following description taken in conjunction with the accompanying drawings.

FIG. 1 is a block diagram showing an exemplary wireless communication system in which an embodiment of the disclosure may be advantageously employed.

FIG. 2 is a block diagram showing a circuit die and an ESD path through the circuit.

FIG. 3 is a block diagram showing a conventional arrangement for preventing damage from ESD events.

FIG. 4 is a block diagram showing an exemplary arrangement for preventing damage from ESD events using an insulating protective layer.

FIG. 5 is a block diagram showing an exemplary arrangement for preventing damage from ESD events using an insulating protective layer after etch processing.

FIG. 6 is a block diagram showing an exemplary arrangement for preventing damage from ESD events using a conducting protective layer.

### DETAILED DESCRIPTION

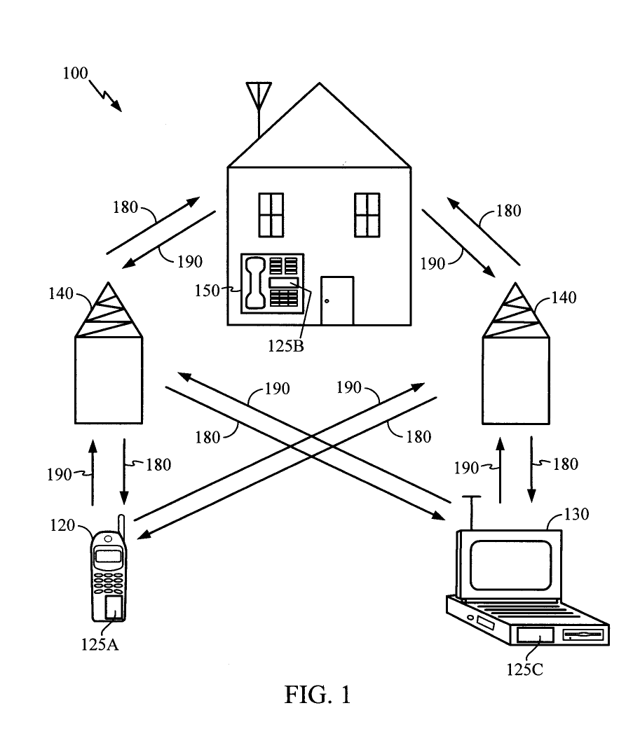

FIG. 1 is a block diagram showing an exemplary wireless communication system 100 in which an embodiment of the disclosure may be advantageously employed. For purposes of illustration, FIG. 1 shows three remote units 120, 130, and 150 and two base stations 140. It will be recognized that typical wireless communication systems may have many more remote units and base stations. Remote units 120, 130, and 150 include IC devices 125A, 125B and 125C, that include the circuitry disclosed here. It will be recognized that any device containing an IC may also include the circuitry disclosed here, including the base stations, switching devices, and network equipment. FIG. 1 shows forward link signals 180 from the base station 140 to the remote units 120, 130, and 150 and reverse link signals 190 from the remote units 120, 130, and 150 to base stations 140.

In FIG. 1, remote unit 120 is shown as a mobile telephone, remote unit 130 is shown as a portable computer, and remote unit 150 is shown as a fixed location remote unit in a wireless local loop system. For example, the remote units may be cell phones, hand-held personal communication systems (PCS) units, portable data units such as personal data assistants, or fixed location data units such as meter reading equipment. Although FIG. 1 illustrates remote units according to the teachings of the disclosure, the disclosure is not limited to these exemplary illustrated units. The disclosure may be suitably employed in any device which includes ESD protection schemes, as described below.

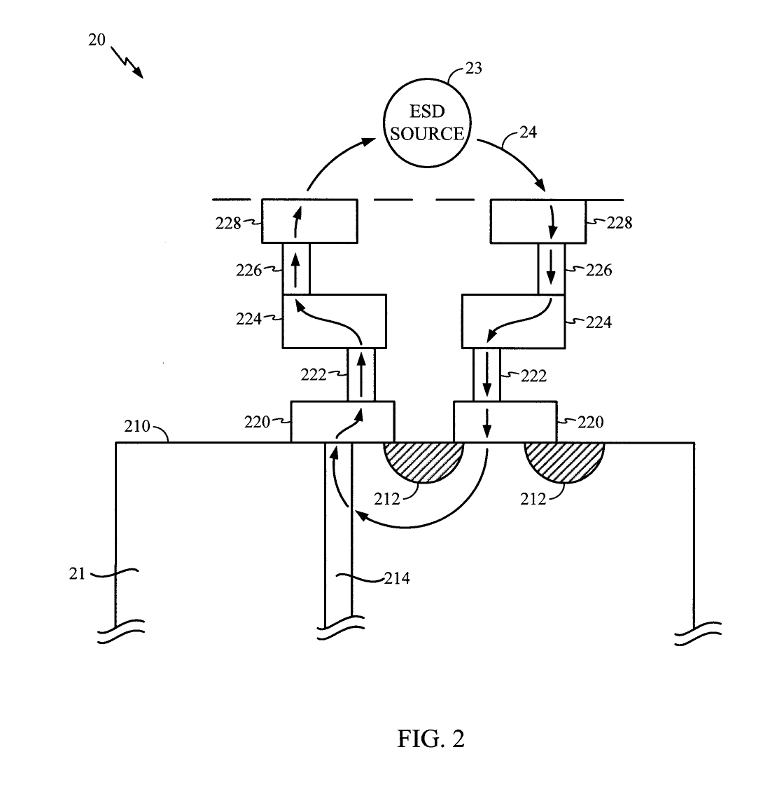

Turning now to FIG. 2, one ESD problem in ICs will be described. FIG. 2 is a block diagram showing a circuit die and an ESD path through the circuit. A device 20 includes a substrate 21 with an active side 210. On the active side 210 is a doped region 212 used in creating the PNP junction for a field effect transistor (FETs). Built on top of the active side 210 are a number of layers specified by design for production of a particular integrated circuit. For example, a contact layer 220 may couple to an interconnect 222 which may be coupled to an intermediate layer 224. The intermediate layer 224 may couple to an interconnect 226 which may be coupled to a tier-to-tier connection 228. Additionally a through silicon via (TSV) 214 is illustrated, which may be coupled to the contact layer 220.

During handling and processing of the wafer, an ESD source 23 at a relatively higher charge than the device 20 may come near or in contact with the substrate 21. For example, an ESD source 23 may come into contact with an exposed connection such as the tier-to-tier connection 228. Near or upon contact with the exposed connection, the ESD source 23 will discharge into the device 20 to reach equilibrium. A current flow 24 will form to make a complete circuit. The current flow 24 will follow the path of least resistance through the device 20. In the present case, this path may be through the tier-to-tier connection 228, the interconnect 226, the intermediate layer 224, the interconnect 222, and the contact layer 220. The current flow 24 then flows through the substrate 21 to the through silicon via 214 and through the contact layer 220, the interconnect 222, the intermediate layer 224, the interconnect 226, and the tier-to-tier connection 228 creating a closed path with the ESD source 23. Anything in the path of the current flow 24 may potentially sustain damage that may result in failure of the device 20 through the mechanisms described earlier.

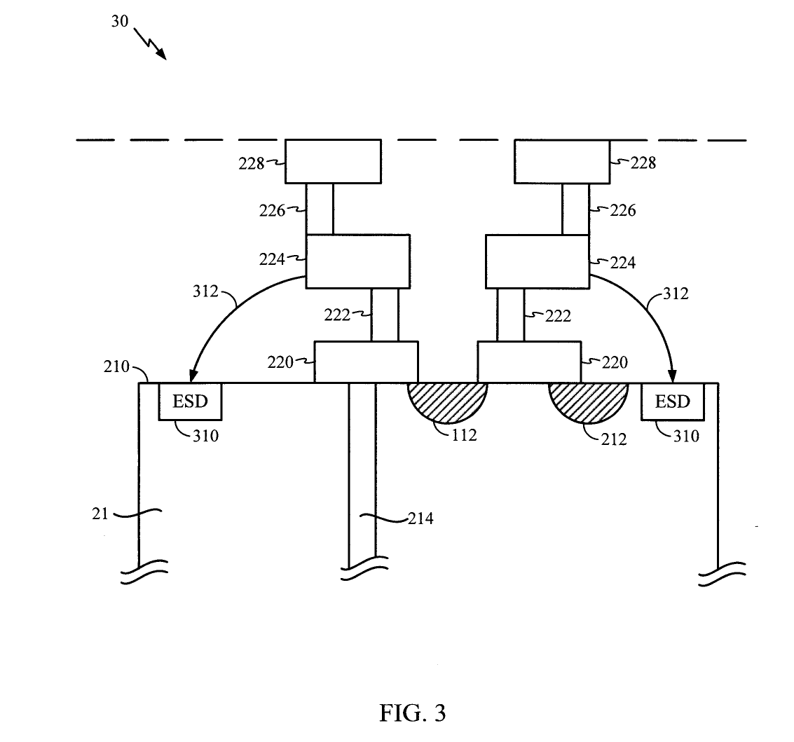

Turning now to FIG. 3, a conventional means for preventing damage from ESD events will be examined. For illustration, a device 30 has a similar circuitry configuration as the device 20. Preventing damage from electrostatic discharge is accomplished by an ESD device 310 connected to the active circuitry by a connection 312. The ESD device may be, for example, a diode for forward bias protection and an additional diode for reverse bias protection. If an electrostatic discharge event occurs sending current though the device 30, the ESD device will create a path of least resistance that diverts the current away from sensitive components and towards the ESD device 310. In the device 30, damage from ESD events is reduced, but at the cost of consuming area that could otherwise be used for active circuitry. Additionally, the ESD device 310 consumes power through leakage currents during device operation. In communications devices that operate from battery power, this power consumption can shorten device operation. Additionally, the ESD device 310 is a parasitic load on the components of the device 30.

According to an aspect of the present disclosure, a device and its components are protected from ESD damage during the manufacturing process while outside controlled environments by depositing a thin film coating on the device. The coating may be an insulator (such as silicon oxide, silicon nitride, or polymer), a semiconductor (such as silicon), or a metal (such as copper). A metal or semiconductor coating provides a path of relatively low resistance for the current flow resulting from an ESD event, thereby preventing the current from damaging sensitive components under the protective layer. Alternatively, an insulator coating prevents the current flow from an ESD event through the components under the protective layer. Several embodiments of the coating will be further described in detail.

According to one embodiment, an insulating protective layer is used to protect the device from ESD events. Some materials that may be used for the insulating protective layer include silicon oxides, silicon nitrides, polymers, photoresist, or spin on glasses (SOGs). The thickness of the protective layer may vary based on the circuit design and the manufacturing process. According to one embodiment, the layer is 100-50000 Angstroms in thickness. If additional ESD prevention is desired, the thickness can be increased. Thicker insulating layers may withstand larger potential differences before experiencing breakdown and allowing current flow from the ESD source to the device. If ESD prevention is sufficient and quicker manufacturing processes are desired, the layer may be thinner. Thinner insulating layers are easier and faster to remove or pattern in future processing. In one embodiment, the layer is thick enough to mechanically withstand transportation.

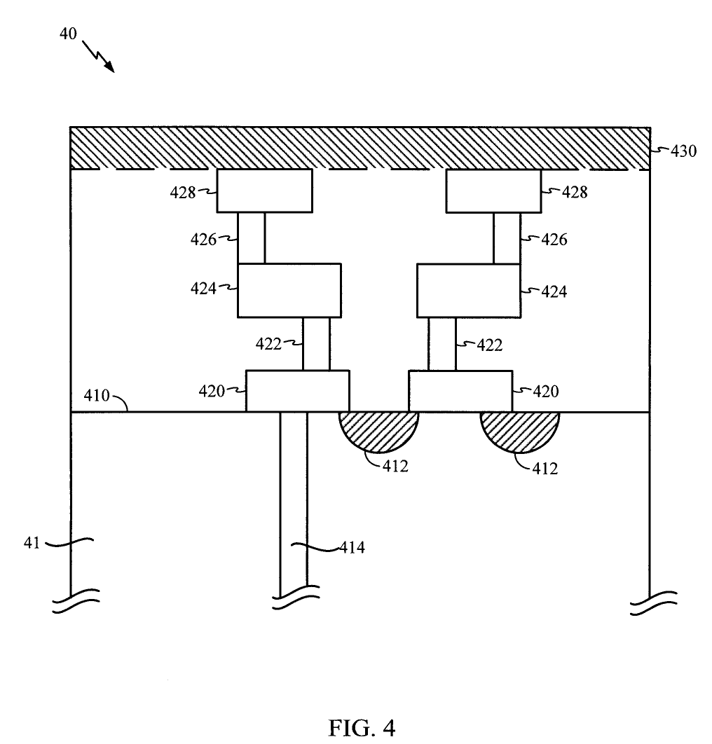

Turning now to FIG. 4, the protective capabilities of an insulator protective layer will be described. FIG. 4 is a block diagram showing an exemplary arrangement for preventing damage from ESD events using an insulating protective layer. For illustration, a device 40 has a similar configuration as the device 20. After the fabrication of a tier-to-tier connection 428 is completed, an oxide layer 430 is deposited on the device 40. The oxide layer 430 is unpatterned and remains a continuous layer of material.

After the insulating protective layer is deposited and the device is transported to a second controlled environment (for example a testing and assembly plant), the insulating protective layer may be removed before assembly of the stacked IC. According to one embodiment, the layer may be stripped using available methods such as wet or dry etching. According to another embodiment, the protective layer may be patterned such that contact can be made to the tier-to-tier connections below the insulating protective layer. Openings in the insulating protective layer are etched away to reveal the tier-to-tier connections below. Metal contacts may then be deposited in the etched openings. These etched openings will now be described in further detail.

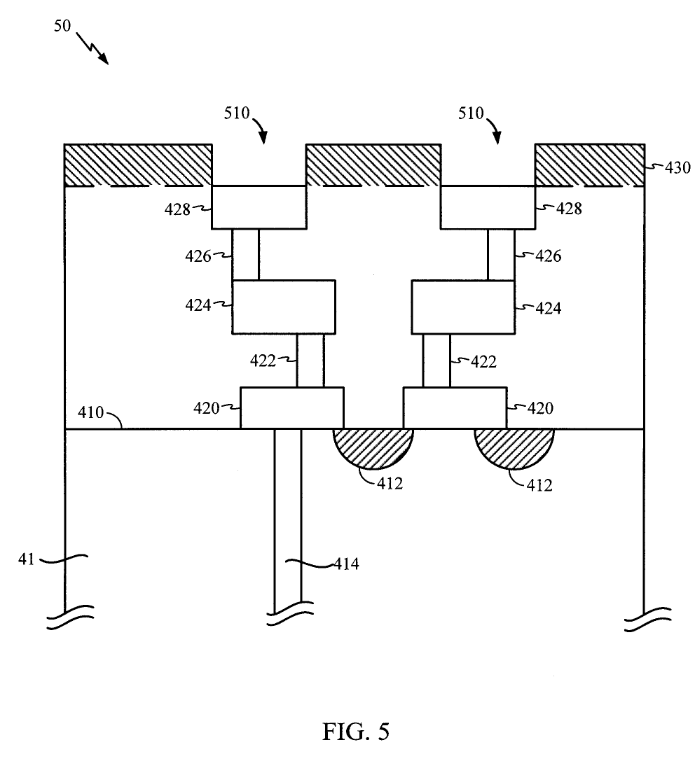

FIG. 5 is a block diagram showing an exemplary arrangement for preventing damage from ESD events using an insulating protective layer after etch processing. For illustration, a device 50 has a similar configuration as the device 40. An opening 510 is etched into the oxide layer 430. Contact to the tier-to-tier connection 428 may be made through the opening 510 allowing additional tiers to be stacked upon the tier 50.

According to another embodiment, a metal protective layer or semiconductor protective layer may protect the device from ESD events outside of controlled environments. In such an arrangement, the final layer of connections is left unpatterned resulting in an unpatterned metal layer remaining on the surface of the device. The layer is left unpatterned such that any current resulting from an ESD event travels through the protective layer instead of through the IC. The final connections are patterned from the protective metal layer after transport to a second fabrication site. The metal could be, for example, copper or aluminum depending on device design. In one embodiment, semiconductor materials, such as poly-silicon are used. The thickness of the protective layer should be thick enough to mechanically withstand transport and electrically withstand current densities anticipated from ESD sources.

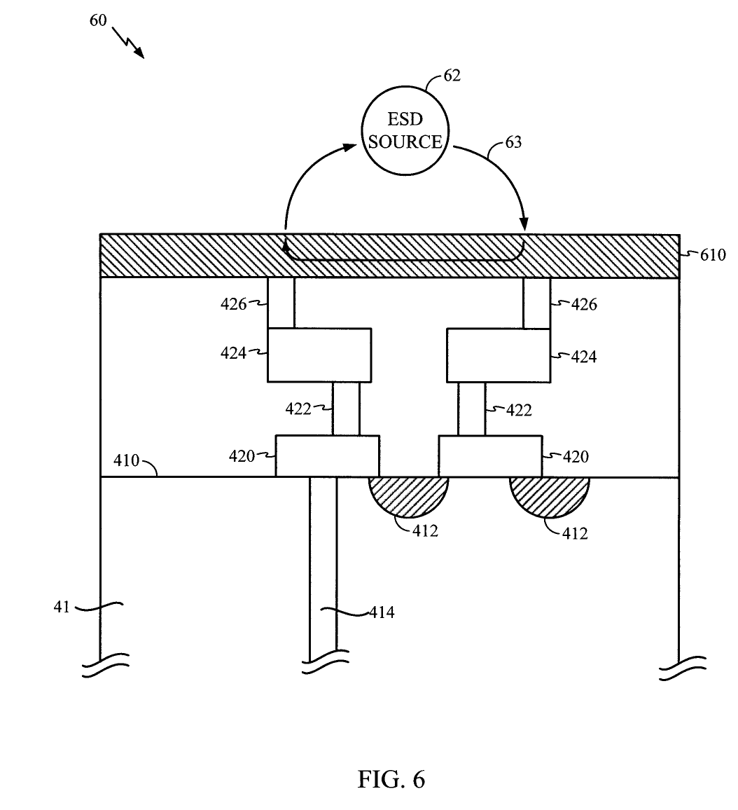

Turning now to FIG. 6, the protective capability of the conducting protective layer are described. FIG. 6 is a block diagram showing an exemplary arrangement for preventing damage from ESD events using a conducting protective layer. For illustration, a device 60 has a similar configuration as the device 20. In this example, the tier-to-tier connection 428 has not been manufactured. Instead, a protective metal layer 610 remains on the surface of the device 60. In the event that the device 60 comes into contact with an ESD source 62, a current flow 63 forms allowing current to flow from the ESD source 62 to the device 60. The protective metal layer 610 is the path of least resistance and the current flow 63 is entirely through the protective metal layer 610. Thus, damage to the components under the protective metal layer 610 is reduced.

In the case of a metal protective layer, no additional costs or procedures are added to the fabrication process. The metal layer typically patterned to form interconnects is left unpatterned such that a continuous metal layer remains on the surface of the die. This metal layer serves as the protective layer until the die reaches another fabrication facility at which time the layer is patterned into interconnects. In the case of an insulator protective layer, additional procedures and layers are implemented; however, the additional cost of these layers is offset by the savings gained from not fabricating ESD devices in the silicon and the savings in occupied silicon area.

Although specific circuitry has been set forth, it will be appreciated by those skilled in the art that not all of the disclosed circuitry is required to practice the disclosure. Moreover, certain well known circuits have not been described, to maintain focus on the disclosure.

Although the present disclosure and its advantages have been described in detail, it should be understood that various changes, substitutions and alterations can be made herein without departing from the technology of the disclosure as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure, processes, machines, manufacture, compositions of matter, means, methods, or steps, presently existing or later to be developed that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. An unassembled stacked IC device, comprising:
an unassembled tier; and
a first unpatterned layer on the unassembled tier, the first unpatterned layer protecting the unassembled tier from ESD events.

2. The unassembled stacked IC device of claim 1, in which the first unpatterned layer thickness is between 100 and 50000 Angstroms.

3. The unassembled stacked IC device of claim 1, in which the first unpatterned layer is a metal layer.

4. The unassembled stacked IC device of claim 3, further comprising a second unpatterned layer on the first unpatterned layer to prevent oxidation of the first unpatterned layer.

5. The unassembled stacked IC device of claim 3, in which the first unpatterned layer may be later patterned into tier-to-tier connections.

6. The unassembled stacked IC device of claim 1, in which the first unpatterned layer is a semiconductor layer.

7. The unassembled stacked IC device of claim 6, in which the first unpatterned layer may be later patterned into tier-to-tier connections.

8. The unassembled stacked IC device of claim 1, in which the first unpatterned layer is an insulator layer.

9. The unassembled stacked IC device of claim 8, in which the first unpatterned layer may be later patterned to expose tier-to-tier connections.

10. The unassembled stacked IC device of claim 8, in which the first unpatterned layer may be later removed to expose tier-to-tier connections.

11. A method for manufacturing a stacked IC device, comprising:
manufacturing a tier of the stacked IC device; and
depositing an unpatterned layer on the tier before transporting to an assembly plant, the unpatterned layer protecting the tier from ESD events.

12. The method of claim 11, in which depositing the unpatterned layer comprises depositing an insulating layer.

13. The method of claim 11, in which depositing the unpatterned layer comprises depositing one of silicon dioxide, silicon nitride, or polymer.

14. The method of claim 11, in which depositing the unpatterned layer comprises depositing a conducting layer.

15. The method of claim 11, in which depositing the unpatterned layer comprises depositing a semiconducting layer.

16. A method for manufacturing a stacked IC device, comprising:
altering an unpatterned layer protecting a tier of a stacked IC device from ESD events to allow the tier of the stacked IC device to be integrated into the stacked IC device; and
integrating the tier into the stacked IC device.

17. The method of claim 16, in which altering the unpatterned layer comprises patterning an insulator layer.

18. The method of claim 17, in which altering the unpatterned layer comprises removing the unpatterned layer to expose tier-to-tier connections of the stacked IC device.

19. The method of claim 17, in which altering the unpatterned layer comprises patterning the unpatterned layer to expose tier-to-tier connections of the stacked IC device.

20. The method of claim 16, in which altering the unpatterned layer comprises patterning a semiconductor layer.

21. The method of claim 20, in which altering the unpatterned layer comprises patterning the unpatterned layer to create tier-to-tier connections.

22. The method of claim 16, in which altering the unpatterned layer comprises patterning a conductor layer.

23. The method of claim 22, in which altering the unpatterned layer comprises patterning the unpatterned layer to create tier-to-tier connections.

24. An unassembled stacked IC device, comprising means for shielding the unassembled stacked IC device from ESD events prior to assembling the stacked IC device.

25. The unassembled stacked IC device of claim 24, in which, after assembling the stacked IC device, the means for shielding is configured into means for connecting a first tier to a second tier.
